(19) United States
(12) Patent Application Publication
(10) Pub. No.: US 2015/0167165 A1
(43) Pub. Date: Jun. 18, 2015

(54) COATING A SUBSTRATE WEB BY ATOMIC LAYER DEPOSITION

(71) Applicant: Sven Lindfors, Espoo (FI)

(72) Inventor: Sven Lindfors, Espoo (FI)

(73) Assignee: Picosun Oy, Espoo (FI)

(21) Appl. No.: 14/407,955

(22) PCT Filed: Jun. 15, 2012
(86) PCT No.: PCT/FI2012/050615

§ 371 Date: Jan. 17, 2015

(51) Int. Cl. C23C 16/455; C23C 16/54

(52) U.S. Cl. CPC C23C 16/45544; C23C 16/54

(57) ABSTRACT

The present invention relates to a method of driving a substrate web (950) into a reaction space of an atomic layer deposition (ALD) reactor and apparatuses therefore. The invention includes driving a substrate web into a reaction space (930) of an atomic layer deposition reactor, and exposing the reaction space to precursor pulses to deposit material on said substrate web by sequential self-saturating surface reactions. One effect of the invention is a simpler structure compared to earlier spatial roll-to-roll ALD reactors. Another effect is that the thickness of deposited material is directly determined by the speed of the web.

### FIELD OF THE INVENTION

The present invention generally relates to deposition reactors. More particularly, the invention relates to atomic layer deposition reactors in which material is deposited on surfaces by sequential self-saturating surface reactions.

### BACKGROUND OF THE INVENTION

Atomic Layer Epitaxy (ALE) method was invented by Dr. Tuomo Suntola in the early 1970's. Another generic name for the method is Atomic Layer Deposition (ALD) and it is nowadays used instead of ALE. ALD is a special chemical deposition method based on the sequential introduction of at least two reactive precursor species to at least one substrate.

Thin films grown by ALD are dense, pinhole free and have uniform thickness. For example, in an experiment aluminum oxide has been grown by thermal ALD from trimethylaluminum (CH₃)₃Al, also referred to as TMA, and water at 250-300° C. resulting in only about 1% non-uniformity over a substrate wafer.

Until now the ALD industry has mainly concentrated on depositing material on one or more rigid substrates. In recent years, however, an increasing interest has been shown towards roll-to-roll ALD processes in which material is deposited on a substrate web unwound from a first roll and wound up around a second roll after deposition.

### SUMMARY

According to a first example aspect of the invention there is provided a method comprising:

driving a substrate web into a reaction space of an atomic layer deposition reactor; and

exposing the reaction space to temporally separated precursor pulses to deposit material on said substrate web by sequential self-saturating surface reactions.

In certain example embodiments, material is deposited on a substrate web and the material growth is controlled by the speed of the web. In certain example embodiments, the substrate web is moved along a straight track through a processing chamber and a desired thin film coating is grown onto the substrate surface by a temporally divided ALD process. In certain example embodiments, each of the phases of an ALD cycle is carried out in one and the same reaction space of a processing chamber. This is in contrast to e.g. spatial ALD in which different phases of a deposition cycle are performed in different reaction spaces.

In certain example embodiments, the whole reaction space may be alternately exposed to precursor pulses. Accordingly, the exposure of the reaction space to a precursor pulse of a first precursor may occur in the exactly same space (or same volume of a processing chamber) as the exposure to a precursor pulse of a second (another) precursor. The ALD process in the reaction space is temporally divided (or time-divided) in contrast to e.g. spatial ALD which requires a reaction space to be spatially divided. The substrate web may be continuously moved or periodically moved through the reaction space. The material growth occurs when the substrate web is within the reaction space and is alternately exposed to precursor vapor pulses to cause sequential self-saturating surface reactions to occur on the substrate web surface. When the substrate web is outside the reaction space in the reactor, substrate web surface is merely exposed to inactive gas, and ALD reactions do not occur.

The reactor can comprise a single processing chamber providing said reaction space. In certain example embodiments, the substrate web is driven from a substrate web source, such as a source roll, into the processing chamber (or reaction space). The substrate web is processed by ALD reactions in the processing chamber and driven out of the processing chamber to a substrate web destination, such as a destination roll. When the substrate web source and destination are rolls, a roll-to-roll atomic layer deposition method is present. The substrate web may be unwound from a first roll, driven into the processing chamber, and wound up around a second roll after deposition. Accordingly, the substrate web may be driven from a first roll to a second roll and exposed to ALD reactions on its way. The substrate web may be bendable. The substrate web may also be rollable. The substrate web may be a foil, such as a metal foil.

In certain example embodiments, the substrate web enters the reaction space from or via a first confined space. The first confined space may be an excess pressure volume. From the reaction space the substrate web may be driven into a second confined space. The second confined space may be an excess pressure volume. It may be the same or another volume as the first confined space. The purpose of the confined space(s) may simply be to prevent precursor vapor/reactive gases from flowing to the outside of the processing chamber via the substrate web route. In a roll-to-roll scenario, the rolls may reside in the confined space or not. The reactor may form part of a production line with processing units in addition to the ALD reactor (or module). Especially then the rolls may reside outside of the confined space(s) further away in suitable point of the production line.

In certain example embodiments, the method comprises:

inputting the substrate web from an excess pressure volume into the reaction space via a slit maintaining a pressure difference between said volume and the reaction space.

The excess pressure herein means that although the pressure in the excess pressure volume is a reduced pressure with regard to the ambient (or room) pressure, it is a pressure higher compared to the pressure in the reaction space. Inactive gas may be fed into the excess pressure volume to maintain said pressure difference. Accordingly, in certain example embodiments, the method comprises:

feeding inactive gas into the excess pressure volume.

In certain example embodiments, the slit (input slit) is so thin that the substrate web just hardly fits to pass through. The excess pressure volume may be a volume in which the first (or source) roll resides. In certain example embodiments, both the first and second roll reside in the excess pressure volume. The excess pressure volume may be denoted as an excess pressure space or compartment. The slit may operate as a flow restrictor, allowing inactive gas to flow from said excess pressure volume to the reaction space (or processing chamber), but substantially preventing any flow in the other direction (i.e., from reaction space to the excess pressure volume). The slit may be a throttle. The slit may operate as a constriction for the inactive gas flow.

In certain example embodiments, the reactor comprises constriction plates forming said slit. The constriction plates may be two plates placed next to each other so that the substrate web just hardly fits to pass through. The plates may be parallel plates so that the space between the plates (slit volume) becomes elongated in the web moving direction.

The substrate web may be unwound from the first roll, ALD processed in a processing chamber providing the reaction space, and wound up on the second roll.

The ALD processed substrate web may output from the reaction space via a second slit (output slit). The structure and function of the second slit may correspond to that of the first mentioned slit. The second slit may reside on the other side of the reaction space compared to the first mentioned slit.

In certain example embodiments, the thickness of deposited material is controlled by the speed of the web. In certain example embodiments, the speed of the web is adjusted by a control unit. The thickness of deposited material may be directly determined by the speed of the web. The web may be driven continuously from said first roll onto the second roll. In certain example embodiment, the web is driven continuously at constant speed. In certain example embodiment, the web is driven by a stop and go fashion. Then the substrate web may be stopped for a deposition cycle, moved upon the end of the cycle, and stopped for the next cycle, and so on. Accordingly, the substrate web may be moved from time to time at predetermined time instants.

In certain example embodiments, the method comprises:

conveying inactive gas into the volume(s) in which the first and second roll reside. Accordingly, the gas in this/these volume(s) may consist of inactive gas. The inactive gas may be conveyed into said volume(s) from a surrounding volume. For example, inactive gas may be conveyed into a reaction chamber accommodating the rolls and surrounding the actual processing chamber from a vacuum chamber that, in turn, surrounds the reaction chamber.

In certain example embodiments, the precursor vapor flow direction in the reaction space is along the moving direction of the substrate web. The substrate web comprises two surfaces and two edges. The precursor vapor may flow along at least one of said surfaces.

In certain example embodiments, the method comprises feeding precursor vapor into the reaction space at the substrate web input end of the reaction space and arranging exhaust of gases at the substrate web output end of the reaction space. Precursor vapor of a first and a second (another) precursor may be alternately conducted into the substrate web input end of the reaction space.

In certain example embodiments, the precursor vapor flow direction in the reaction space is traverse compared to the moving direction of the substrate web. The substrate web comprises two surfaces and two edges. The traverse precursor vapor flow direction may be along at least one of said surfaces.

In certain example embodiments, the method comprises:

feeding precursor vapor into the reaction space at a side of the reaction space and arranging exhaust of gases at an opposite side of the reaction space.

In certain example embodiments, the method comprises:

alternately feeding precursor vapor of a first precursor into the reaction space at a first side of the reaction space and precursor vapor of a second (another) precursor at the first side or a second (opposite) side of the reaction space, and arranging exhaust of gases at the middle area of the reaction space or at the substrate web output end of the reaction space.

In certain example embodiments, the method comprises:

integrating the first and second roll into a reaction chamber lid.

The atomic layer deposition reactor may be reactor with nested chambers. In certain example embodiments, the reactor comprises a first chamber (a vacuum chamber, or a first pressure vessel) surrounding and housing a second chamber (a reaction chamber, or a second pressure vessel). The reaction chamber houses the first and second roll, and inside the reaction chamber may be formed a third chamber (the processing chamber) providing said reaction space. In certain example embodiments, the processing chamber is integrated into the reaction chamber lid.

The reactor may be loaded and unloaded from the top of the reactor/reaction chamber. In certain example embodiments, the reaction chamber lid (which may be a dual lid system providing also a lid to the vacuum chamber) is raised into an upper position for loading. The first roll and second roll are attached to the lid. The lid is lowered so that the reaction chamber (and vacuum chamber) closes. Feeding of gases into the reaction space may occur from precursor/inactive gas sources via the reaction chamber lid.

In certain example embodiments, the method comprises:

driving said substrate web straight through said reaction space.

In other embodiments, the web may be arranged to follow a longer track within the reaction space to enable larger capacity.

In certain example embodiments, the method comprises:

using a narrow processing chamber that is, in its lateral direction, as wide as the substrate web.

Especially when the processing chamber is not substantially wider than the substrate web, material may be deposited on a single side of the substrate web, since the substrate itself prevents gases from flowing onto the other side of the web. The substrate web, said slit(s) and the processing chamber may all be substantially equal in width. Basically, embodiments in which the substrate web travels close to the processing chamber wall (in the direction of desired material growth) suit well for single-sided deposition, whereas embodiments in which the substrate travels in the center area of the processing chamber/reaction space suit well for double-sided deposition.

In certain example embodiments, the method comprises feeding inactive gas into a space between a backside of the substrate web and processing chamber wall to form a shielding volume. The shielding volume is formed against deposition on the backside of the substrate web, the backside thus being the surface of the substrate web that is not to be coated.

In certain example embodiments, the reactor comprises separate precursor vapor in-feed openings for both surfaces of the substrate web.

According to a second example aspect of the invention there is provided an apparatus comprising:

a driving unit configured to drive a substrate web into a reaction space of an atomic layer deposition reactor; and

a precursor vapor feeding part configured to expose the reaction space to temporally separated precursor pulses to deposit material on said substrate web by sequential self-saturating surface reactions.

The apparatus may be an atomic layer deposition (ALD) reactor. The ALD reactor may be a standalone apparatus or a part of a production line. The driving unit may be configured to drive the substrate web from a first roll via the reaction space to a second roll. The driving unit may be connected to the second (destination) roll. In certain example embodiments, the driving unit comprises a first drive that is connected to the first (source) roll and a second drive that is connected to the second (destination) roll, respectively. The driving unit may be configured to rotate the roll(s) at a desired speed.

In certain example embodiments, a precursor vapor feeding part comprises a plurality of shower heads arranged inside the reaction space to deliver precursor vapor into the reaction space. In certain example embodiments, a reaction chamber lid forms a precursor vapor feeding part.

In certain example embodiments, the apparatus comprises:

an input slit for inputting the substrate web from an excess pressure volume into the reaction space.

In certain example embodiments, the slit is for maintaining a pressure difference between said volume and the reaction space. In certain example embodiments, the apparatus comprises constriction plates forming said slit.

In certain example embodiments, the apparatus comprises:

a channel configured to convey inactive gas into the excess pressure volume.

In certain example embodiments, said channel is from a vacuum chamber via reaction chamber wall or lid into the reaction chamber.

In certain example embodiments, the apparatus comprises:

a precursor vapor in-feed opening at the substrate web input end of the reaction space and exhaust at the substrate web output end of the reaction space.

In certain example embodiments, the apparatus comprises:

a precursor vapor in-feed opening or openings at a side of the reaction space and exhaust at an opposite side of the reaction space.

The apparatus may have a precursor vapor in-feed opening or openings at a side of the reaction space substantially throughout the reaction space in its longitudinal direction.

The directions of the reaction space may be defined as follows: substrate web moving direction, direction of desired material growth (a direction perpendicular to the substrate web moving direction), and a traverse direction (a direction perpendicular to both the substrate web moving direction and the direction of desired material growth). Said longitudinal direction of the reaction space means a direction parallel to the substrate web moving direction.

In certain example embodiments, the apparatus comprises:

a reaction chamber lid configured to receive the first and second roll.

In an example embodiment, the reaction chamber lid comprises roll holders integrated to it for receiving the first and second roll.

In certain example embodiments, the reaction chamber lid comprises an attachment or an attachment mechanism to which the first and second roll can be attached. The beginning portion of the substrate web may be drawn through the processing chamber onto the second roll before the lid is lowered.

In certain example embodiments, the apparatus comprises:

a narrow processing chamber that is, in its lateral direction, as wide as the input slit. Said lateral direction means said traverse direction. The apparatus may further comprise a control unit configured to control the operation of the reactor, such as timing of the precursor pulses and purge periods. The control unit may also control the operation of the driving unit. In certain example embodiments, the control unit adjusts the speed of the substrate web to control thickness of desired material growth .

According to a third example aspect of the invention there is provided an apparatus comprising:

means for driving a substrate web into a reaction chamber of an atomic layer deposition reactor; and

means for exposing the reaction space to temporally separated precursor pulses to deposit material on said substrate web by sequential self-saturating surface reactions.

Different non-binding example aspects and embodiments of the present invention have been illustrated in the foregoing. The above embodiments are used merely to explain selected aspects or steps that may be utilized in implementations of the present invention. Some embodiments may be presented only with reference to certain example aspects of the invention. It should be appreciated that corresponding embodiments may apply to other example aspects as well. Any appropriate combinations of the embodiments may be formed.

### BRIEF DESCRIPTION OF THE DRAWINGS

The invention will now be described, by way of example only, with reference to the accompanying drawings, in which:

FIG. 1 shows a side view of a deposition reactor in a loading phase in accordance with an example embodiment;

FIG. 2 shows the deposition reactor of FIG. 1 in operation during a purge step in accordance with an example embodiment;

FIG. 3 shows the deposition reactor of FIG. 1 in operation during a precursor exposure period in accordance with an example embodiment;

FIG. 4 shows a top view of a thin processing chamber of the deposition reactor of FIG. 1 and a cross section at an input slit in accordance with an example embodiment;

FIG. 5 shows the deposition reactor of FIG. 1 after ALD processing has been finished in accordance with an example embodiment;

FIG. 6 shows a single drive system in accordance with an example embodiment;

FIG. 7 shows a side view of a deposition reactor in a loading phase in accordance with another example embodiment;

FIG. 8 shows the deposition reactor of FIG. 7 in operation during a precursor exposure period in accordance with an example embodiment;

FIG. 9 shows a side view of a deposition reactor in accordance with a generic example embodiment;

FIG. 10 shows the deposition reactor of FIG. 9 in operation during a precursor exposure period in accordance with an example embodiment;

FIG. 11 shows a top view of the deposition reactor of FIG. 9 during the precursor exposure period of FIG. 7 in accordance with an example embodiment;

FIG. 12 shows the deposition reactor of FIG. 9 in operation during another precursor exposure period in accordance with an example embodiment;

FIG. 13 shows a deposition reactor with constriction plates in accordance with an example embodiment;

FIG. 14 shows thickness of deposited material in the function of distance traveled within a reaction space in accordance with an example embodiment;

FIG. 15 shows a deposition reactor with precursor vapor in-feed at the substrate web input end of the processing chamber in accordance with an example embodiment;

FIG. 16 shows a top view of the type of deposition reactor of FIG. 15 in accordance with an example embodiment;

FIG. 17 shows a deposition reactor with precursor vapor in-feed at the side of the processing chamber in accordance with an example embodiment;

FIG. 18 shows a top view of the type of deposition reactor of FIG. 17 in accordance with an example embodiment;

FIG. 19 shows an alternative construction in accordance with an example embodiment;

FIG. 20 shows a top view of a deposition reactor in accordance with yet another example embodiment;

FIG. 21 shows a top view of a deposition reactor for deposition of multiple rolls at a time in accordance with an example embodiment;

FIG. 22 shows a thin reactor structure in accordance with an example embodiment;

FIG. 23 shows a thin reactor structure for deposition of multiple rolls in accordance with an example embodiment;

FIG. 24 shows double-sided coating in accordance with an example embodiment;

FIG. 25 shows a specific detail for single-sided coating in accordance with an example embodiment; and

FIG. 26 shows a rough block diagram of a deposition reactor control system in accordance with an example embodiment.

### DETAILED DESCRIPTION

In the following description, Atomic Layer Deposition (ALD) technology is used as an example. The basics of an ALD growth mechanism are known to a skilled person. As mentioned in the introductory portion of this patent application, ALD is a special chemical deposition method based on the sequential introduction of at least two reactive precursor species to at least one substrate. The substrate, or the moving substrate web in this case, is located within a reaction space. The reaction space is typically heated. The basic growth mechanism of ALD relies on the bond strength differences between chemical adsorption (chemisorption) and physical adsorption (physisorption). ALD utilizes chemisorption and eliminates physisorption during the deposition process. During chemisorption a strong chemical bond is formed between atom(s) of a solid phase surface and a molecule that is arriving from the gas phase. Bonding by physisorption is much weaker because only van der Waals forces are involved.

The reaction space of an ALD reactor comprises all the typically heated surfaces that can be exposed alternately and sequentially to each of the ALD precursor used for the deposition of thin films or coatings. A basic ALD deposition cycle consists of four sequential steps: pulse A, purge A, pulse B and purge B. Pulse A typically consists of metal precursor vapor and pulse B of non-metal precursor vapor, especially nitrogen or oxygen precursor vapor. Inactive gas, such as nitrogen or argon, and a vacuum pump are typically used for purging gaseous reaction by-products and the residual reactant molecules from the reaction space during purge A and purge B. A deposition sequence comprises at least one deposition cycle. Deposition cycles are repeated until the deposition sequence has produced a thin film or coating of desired thickness.

In a typical ALD process, precursor species form through chemisorption a chemical bond to reactive sites of the heated surfaces. Conditions are typically arranged in such a way that no more than a molecular monolayer of a solid material forms on the surfaces during one precursor pulse. The growth process is thus self-terminating or saturative. For example, the first precursor can include ligands that remain attached to the adsorbed species and saturate the surface, which prevents further chemisorption. Reaction space temperature is maintained above condensation temperatures and below thermal decomposition temperatures of the utilized precursors such that the precursor molecule species chemisorb on the substrate(s) essentially intact. Essentially intact means that volatile ligands may come off the precursor molecule when the precursor molecules species chemisorb on the surface. The surface becomes essentially saturated with the first type of reactive sites, i.e. adsorbed species of the first precursor molecules. This chemisorption step is typically followed by a first purge step (purge A) wherein the excess first precursor and possible reaction by-products are removed from the reaction space. Second precursor vapor is then introduced into the reaction space. Second precursor molecules typically react with the adsorbed species of the first precursor molecules, thereby forming the desired thin film material or coating. This growth terminates once the entire amount of the adsorbed first precursor has been consumed and the surface has essentially been saturated with the second type of reactive sites. The excess of second precursor vapor and possible reaction by-product vapors are then removed by a second purge step (purge B). The cycle is then repeated until the film or coating has grown to a desired thickness. Deposition cycles can also be more complex. For example, the cycles can include three or more reactant vapor pulses separated by purging steps. All these deposition cycles form a timed deposition sequence that is controlled by a logic unit or a microprocessor.

FIG. 1 shows a side view of a deposition reactor in a loading phase in accordance with an example embodiment. The deposition reactor comprises vacuum chamber wall(s) 111 to form a vacuum chamber 110. The vacuum chamber 110 is a pressure vessel. It can be in the form of a cylinder or any other suitable shape. The vacuum chamber 110 houses a reaction chamber 120, which is another pressure vessel. The reaction chamber 120 be in the form of a cylinder or any other suitable shape. The vacuum chamber 110 is closed by a vacuum chamber lid 101. In an example embodiment, the vacuum chamber lid 101 is integrated to a reaction chamber lid 102 as shown in FIG. 1 thereby forming a lid system (here: a dual-lid system). A processing chamber 130 comprising processing chamber walls 131 has been attached to the reaction chamber lid 102 by fastener(s) 185. Between the reaction chamber lid 102 and the vacuum chamber lid 101, the lid system comprises heat reflectors 171.

A first (source) roll 151 of substrate web 150 is attached to a first roll axis 143. The roll axis (or roll 151) can be rotated by a first drive 141 attached to the roll axis 143. The drive 141 is located outside of the vacuum chamber 110. It is attached to the lid system by a fastener 147. There is a lead-through in the lid system (both in the vacuum chamber lid 101 and in the reaction chamber lid 102) via which the roll axis 143 penetrates into the reaction chamber 120. In the bottom of the reaction chamber 120, there is an attachment 145 for attaching the roll axis 143 to the reaction chamber 120. The roll 151 can be attached to the roll axis 143 by an appropriate attachment 106. The roll axis 143 and the attachment 106 form a roll holder.

A second (destination) roll 152 is attached to a second roll axis 144. The roll axis (or roll 152) can be rotated by a second drive 142 attached to the roll axis 144. The drive 142 is located outside of the vacuum chamber 110. It is attached to the lid system by a fastener 148. There is a lead-through in the lid system (both in the vacuum chamber lid 101 and in the reaction chamber lid 102) via which the roll axis 144 penetrates into the reaction chamber 120. In the bottom of the reaction chamber 120, there is an attachment 146 for attaching the roll axis 144 to the reaction chamber 120. Similarly, as the roll 151, the roll 152 can be attached to the roll axis by an appropriate attachment 107. The roll axis 144 and the attachment 107 therefore form another roll holder.

In the vacuum chamber 110 around the reaction chamber 120 (or in the reaction chamber 120 around the processing chamber 130 in some embodiments), the deposition reactor comprises a heater 175 for heating the reaction space formed within the processing chamber 130. At the side, between the vacuum chamber wall 111 and reaction chamber wall 121, the vacuum chamber 110 comprises heat reflectors 172.

The deposition reactor comprises an upper interface flange 104 attached to a reaction chamber top flange 103. A seal 181 is placed between the vacuum chamber lid 101 and the upper interface flange 104 to seal the top part of the vacuum chamber 110. The reaction chamber 120 comprises a reaction chamber top flange 105. Upon lowering the lid system the reaction chamber lid 102 sets on the reaction chamber top flange 105, thereby closing the reaction chamber 120.

The deposition reactor further comprises a vacuum pump 160 and an exhaust line 161, which during operation is in fluid communication from the processing chamber 130 to the vacuum pump 160.

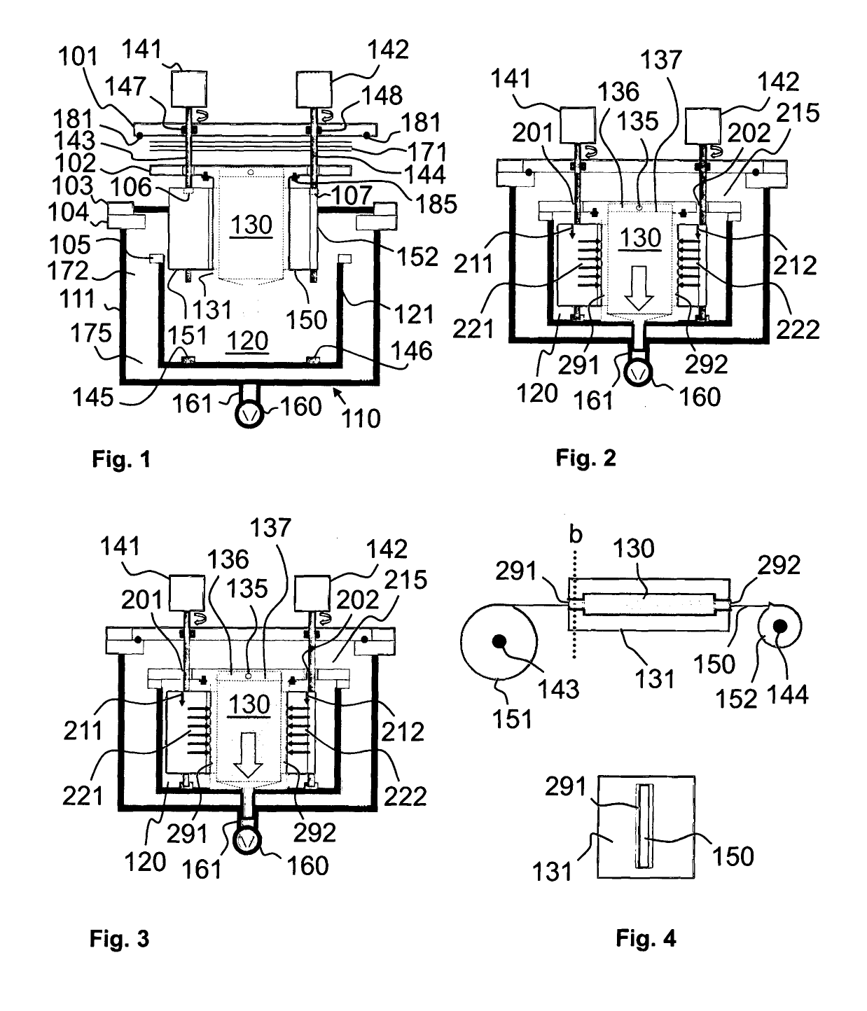

The deposition reactor is loaded with the lid system in its upper position. The source roll 151 with bendable or rollable substrate web is attached into the roll axis 143. A first end of the substrate web 150 is brought through the processing chamber 130 to the destination roll 152 and attached thereto. The lid system is subsequently lowered to close the chambers. In an embodiment, the processing chamber 130 comprises a protruding channel at the bottom. The protruding channel passes through an opening in the reaction chamber 120 and forms the beginning of the exhaust line 161 when the lid system has been lowered as depicted in FIG. 2.

Moreover, FIG. 2 shows the deposition reactor of FIG. 1 in operation during a purge step in accordance with an example embodiment. The substrate web 150 enters the processing chamber (reaction space) 130 via a slit 291 arranged into the processing chamber wall 131. Inactive gas flows into the processing chamber 130 via reaction chamber lid 102. It flows from an inlet 135 into an expansion volume 136. The gas spreads within the expansion volume 136 and flows through a flow distributor 137 (such as a perforated plate or a mesh) into the reaction space of the processing chamber 130. The inactive gas purges the substrate web surface and flows as a top-to-bottom flow into the exhaust line 161 and finally to the vacuum pump 160. The substrate web 150 is output from the reaction space 130 via a slit 292 arranged into the processing chamber wall 131. The output substrate web is wound around the destination roll 152.

The reaction chamber 120 has at least one opening to the vacuum chamber 110. In the example embodiment shown in FIG. 2, a first opening 201 is arranged at the lead-through at which the roll axis 143 penetrates through the reaction chamber lid 102. There is an inlet of inactive gas into the vacuum chamber (outside of the reaction chamber 120). This inactive gas flows through the opening 201 from an intermediate space 215 (between the vacuum chamber and reaction chamber) to the reaction chamber 120 into the confined space where the rolls 151 and 152 reside. This flow is depicted by arrow 211. Similarly, a second opening 202 is arranged at the lead-through at which the roll axis 144 penetrates through the reaction chamber lid 102. Inactive gas flows from the intermediate space 215 to the reaction chamber 120 into the confined space where the rolls 151 and 152 reside. This flow is depicted by arrow 212.

The slits 291 and 292 function as throttles maintaining a pressure difference between the reaction space of the processing chamber 130 and the surrounding volume (such as the confined space in which the rolls 151 and 152 reside). The pressure within the confined space is higher than the pressure within the reaction space. As an example, the pressure within the reaction space may be 1 mbar while the pressure within the confined space is for example 5 mbar. The pressure difference forms a barrier preventing a flow from the reaction space into the confined space. Due to the pressure difference, however, flow from the other direction (that is, from the confined space to the reaction space through the slits 291 and 292 is possible). As to the inactive gas flowing from the inlet 135 (as well as precursor vapor during precursor vapor pulse periods), this flow therefore practically only sees the vacuum pump 160. In FIG. 2 the flow from the reaction chamber (confined space) to the reaction space is depicted by the arrows 221 and 222.

FIG. 3 shows the deposition reactor of FIG. 1 in operation during a precursor exposure period in accordance with an example embodiment. Precursor vapor of a first precursor flows into the processing chamber 130 via reaction chamber lid 102. It flows from the inlet 135 into the expansion volume 136. The gas spreads within the expansion volume 136 and flows through the flow distributor 137 into the reaction space of the processing chamber 130. The precursor vapor reacts with the reactive sites on substrate web surface in accordance with ALD growth mechanism.

As mentioned in the preceding, the pressure difference between the reaction space and the confined space where the rolls 151 and 152 are located forms a barrier preventing a flow from the reaction space into the confined space. The precursor vapor does therefore not substantially enter the space where the rolls 151 and 152 are. Due to the pressure difference, however, flow from the other direction (that is, from the confined space to the reaction space through the slits 291 and 292) is possible.

Inactive gas, gaseous reaction by-products (if any) and residual reactant molecules (if any) flow into the exhaust line 161 and finally to the vacuum pump 160.

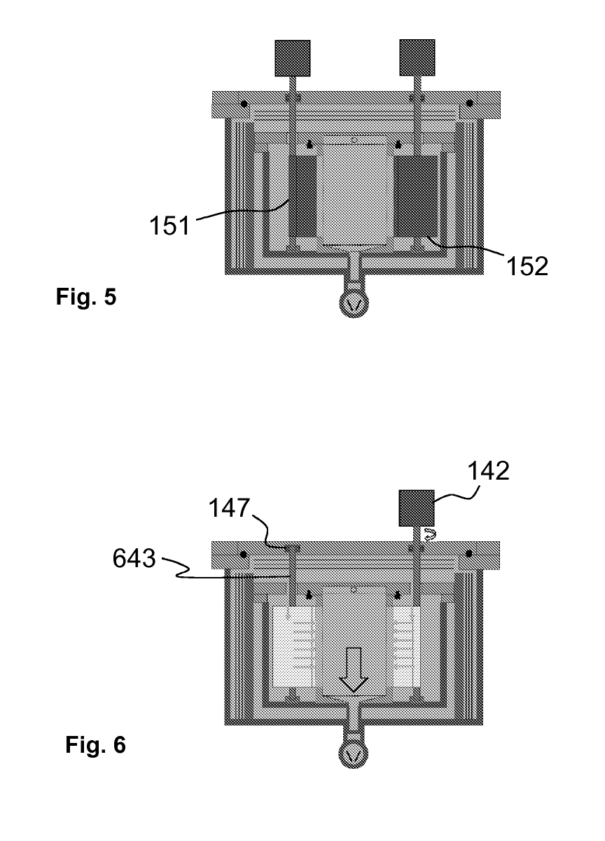

A deposition sequence is formed of one or more consecutive deposition cycles, each cycle consisting of at least a first precursor exposure period (pulse A) followed by a first purge step (purge A) followed by a second precursor exposure period (pulse B) followed by a second purge step (purge B). The thickness of grown material is determined by the speed of the web. The substrate web is driven by the drives 141 and 142. During a single deposition cycle the substrate web moves a certain distance d. If the total length of the reaction space is D, the number of layers deposited on the substrate web basically becomes D/d. When the desired length of substrate web has been processed, the lid system is raised and the deposited roll is unloaded from the reactor. FIG. 5 shows the end position in a deposition process in which the source roll 151 has become empty and the destination roll 152 full with deposited coating.

The upper drawing of FIG. 4 shows a top view of the processing chamber 130 in an example embodiment. The processing chamber 130 is a thin processing chamber with said slits 291 and 292 arranged into the processing chamber walls 131. The moving substrate web 150 is input into the (narrow) reaction space via slit 291 and output via slit 292. The flow of precursor vapor from the reaction space to the outside of the reaction space is prevented firstly by the narrowness of the slits and secondly by the maintained pressure difference.

The lower drawing of FIG. 4 shows a cross section of the processing chamber 130 at the input slit 291 (line b) in accordance with an example embodiment. In the longitudinal direction of the slit the substrate web 150 is substantially matched with the length of the slit 291 (the substrate web 150 is as wide as the slit 291 is long).

In certain example embodiments, the drives 141 and 142 rotate the rolls 151 and 152 in the same direction during the whole deposition sequence. In these example embodiments, it is actually enough to have one drive, namely the second drive 142. In certain other example embodiments, the roll direction of the rolls 151 and 152 is changed in the middle of the deposition sequence. In these embodiments, in the end of the deposition sequence it is the first roll 151 that is full and the second roll 152 empty.

FIG. 6 shows a single drive system in accordance with an example embodiment. The substrate web is driven by the drive 142. The roll axis 643 (basically corresponding to roll axis 143 in FIG. 1) is attached to the fastener 147. Otherwise as to the structural and functional features of the embodiment of FIG. 6 a reference is made to FIGS. 1-5 and their description.

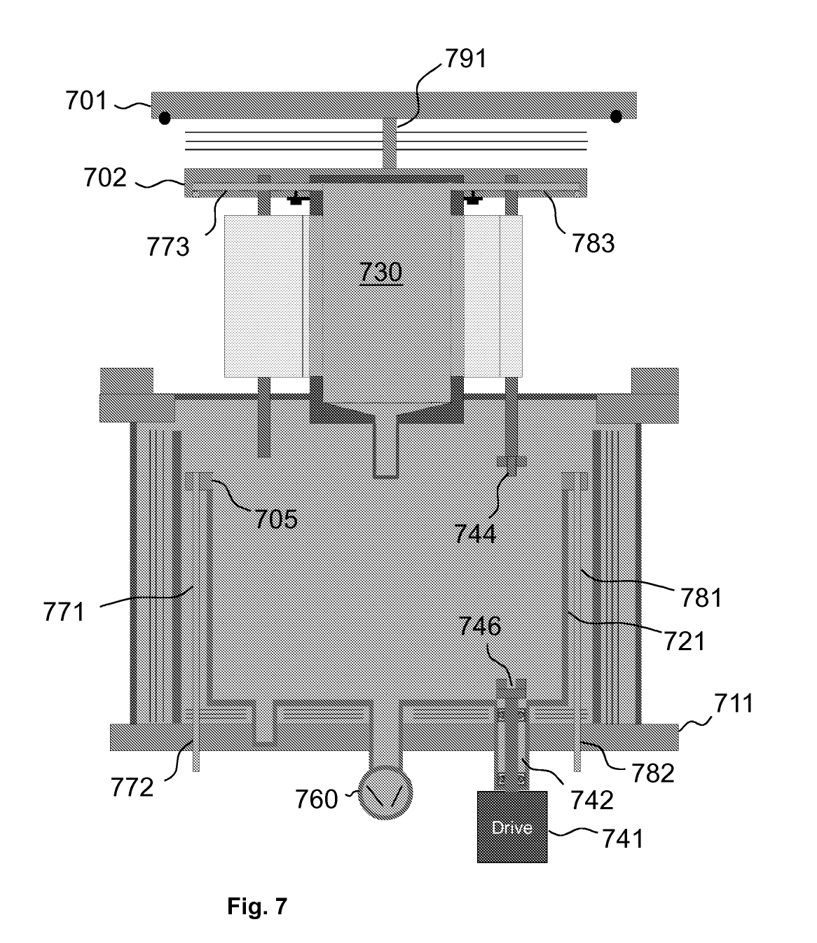

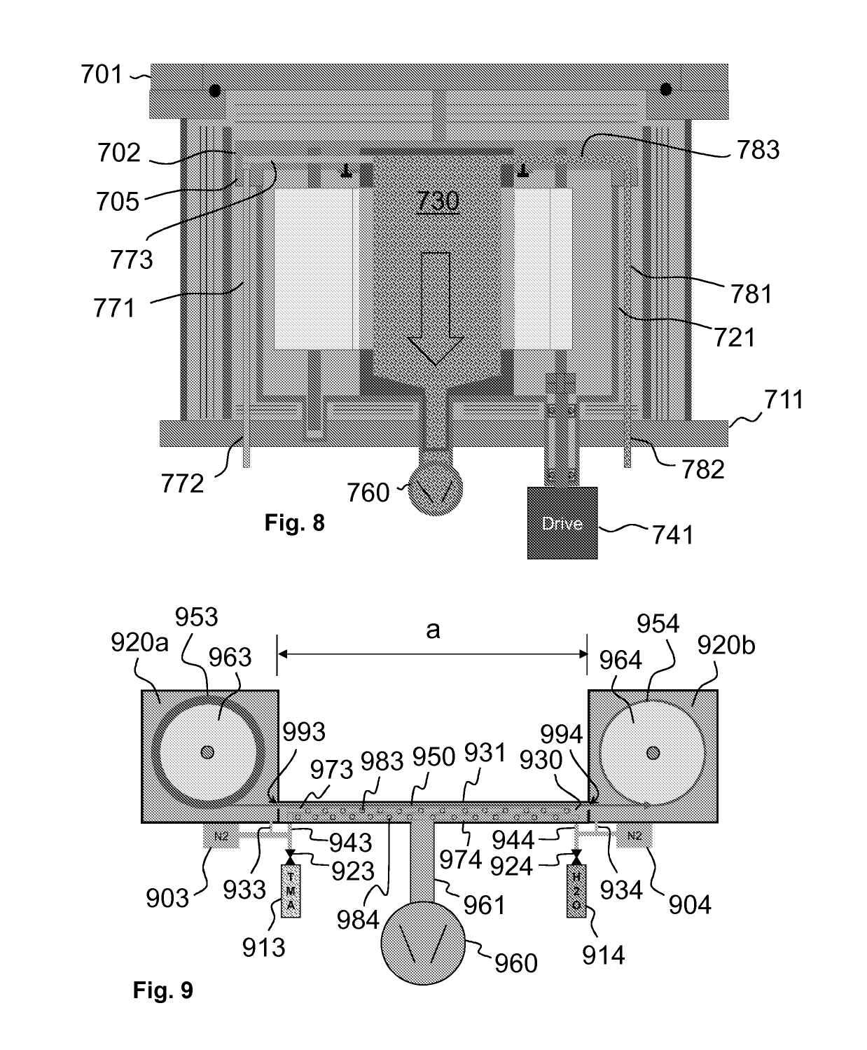

FIG. 7 shows a side view of a deposition reactor in a loading phase in accordance with another example embodiment, and FIG. 8 shows the deposition reactor of FIG. 7 in operation during a precursor exposure period in accordance with an example embodiment. As to the basic structural and functional features of the embodiments of FIGS. 7 and 8 a reference is made to the embodiments described in the foregoing with reference to FIGS. 1-6 and related description.

In the embodiments shown in FIGS. 7 and 8, a drive 741 is located below the vacuum chamber. A driving mechanism 742 of drive 741 penetrates into the reaction chamber through a vacuum chamber wall 711 and a reaction chamber wall 721 by a vacuum and reaction chamber lead-through. An end part 744 or the second roll axis fits into a counterpart 746 of the driving mechanism 742.

A first precursor in-feed line 771 penetrates through the vacuum chamber wall 711 by a vacuum chamber lead-through 772. And a second precursor in-feed line 781 penetrates through the vacuum chamber wall 711 by a vacuum chamber lead-through 782. The vacuum chamber lid 701 is integrated to the reaction chamber lid 702 by a connecting part 791. The first and second precursor in-feed lines 771 and 781 go through the reaction chamber top flange 705 and continue inside of the reaction chamber lid 702 as depicted by reference numerals 773 and 783. The in-feed lines 771 and 781 open to the processing chamber 730.

The route of the second precursor during the second precursor exposure period as shown in FIG. 8 is via the second precursor in-feed line 781 into the reaction space of the processing chamber 730. Via the first precursor in-feed line 771 into the processing chamber only an inactive gas flow is maintained. The route of the gases out of the reaction space is the route to the vacuum pump 760 due to the barrier formation at substrate web input and output slits as described in the foregoing.

FIG. 9 shows a side view of a deposition reactor in accordance with another example embodiment. The deposition reactor comprises a first precursor source 913, which is for example a TMA (trimethylaluminium) source, and a second precursor source 914, which is for example a H₂O (water) source. In this and in other embodiments, the water source can be replaced by an ozone source. A first pulsing valve 923 controls the flow of precursor vapor of the first precursor into a first precursor in-feed line 943. A second pulsing valve 924 controls the flow of precursor vapor of the second precursor into a second precursor in-feed line 944.

The deposition reactor further comprises a first inactive gas source 903. For example nitrogen N₂ can be used as the inactive gas is many embodiments. The first inactive gas source 903 is in fluid communication with the first precursor in-feed line 943. The first inactive gas source 903 is further in fluid communication with a confined space 920a that contains a first roll core 963 having bendable substrate web wound thereon to form a first (source) substrate web roll 953.

The deposition reactor further comprises a second inactive gas source 904. However, the inactive gas sources 903 and 904 may be implemented as a single source in some example embodiments. The second inactive gas source 904 is in fluid communication with the second precursor in-feed line 944. The second inactive gas source 904 is further in fluid communication with a confined space 920b that contains a second roll core 964 having bendable substrate web to be wound thereon to form a second (destination) substrate web roll 954.

The deposition reactor further comprises a processing chamber providing a reaction space 930 with the length of a. The in-feed lines 943 and 944 enter the processing chamber and continue in the processing chamber as shower head channels 973 and 974, respectively. In the example embodiment of FIG. 9 the showerhead channels 973 and 974 are horizontal channels. The shower head channels 973 and 974 reach from one end to the other end of the processing chamber (or reaction space). On their length the shower head channels 973 and 974 have apertures 983 and 984, respectively, which function as shower heads for in-feed gases (such as precursor vapor and/or inactive gas).

The deposition reactor further comprises a vacuum pump 960 and an exhaust line 961, which during operation is in fluid communication from the reaction space 930 to the vacuum pump 960.

Moreover, FIG. 9 shows the deposition reactor in operation during a purge step in accordance with an example embodiment. The substrate web 950 enters the processing chamber (reaction space 930) via a slit or narrow passage 993 arranged between the confined space 920a and the reaction space 930. The pulsing valves 923 and 924 are closed. Inactive gas flows into the processing chamber via in-feed lines 943 and 944 and into the reaction space 930 via apertures 983 and 984. The inactive gas purges the substrate web 950 surface and flows as a horizontal flow into the exhaust line 961 and finally to the vacuum pump 960. The substrate web 950 is output from the reaction space 930 via a slit or narrow passage 994 arranged between the confined space 920b and the reaction space 930. The output substrate web is wound around the second roll core 964 to form the destination roll 954.

The slits 993 and 994 function as throttles maintaining a pressure difference between the reaction space 930 and the confined space in which the rolls 953 and 954 are located. Inactive gas flows via confined space in-feed channels 933 and 934 into the confined spaces 920a and 920b, respectively. The pressure within the confined space(s) 920a and 920b is higher than the pressure within the reaction space 930. As an example, the pressure within the reaction space 930 may be 1 mbar while the pressure within the confined space(s) 920a and 920b is for example 5 mbar. The pressure difference forms a barrier preventing a flow from the reaction space 930 into the confined space(s) 920a and 920b. Due to the pressure difference, however, flow from the other direction (that is, from the confined space(s) 920a and 920b to the reaction space 930 through the slits 993 and 994 is possible). As to the inactive gas flowing via shower heads 983 and 984 (as well as precursor vapor during precursor vapor pulse periods), these flows therefore practically only see the vacuum pump 960.

The track of the substrate web 950 can be arranged close to a processing chamber wall 931. If the substrate web is in the lateral direction is substantially as wide as the reaction space or processing chamber 930 and the substrate web is impermeable with regard to the used precursors it is possible, depending on the implementation, to deposit material on a single side (down side) of the substrate web.

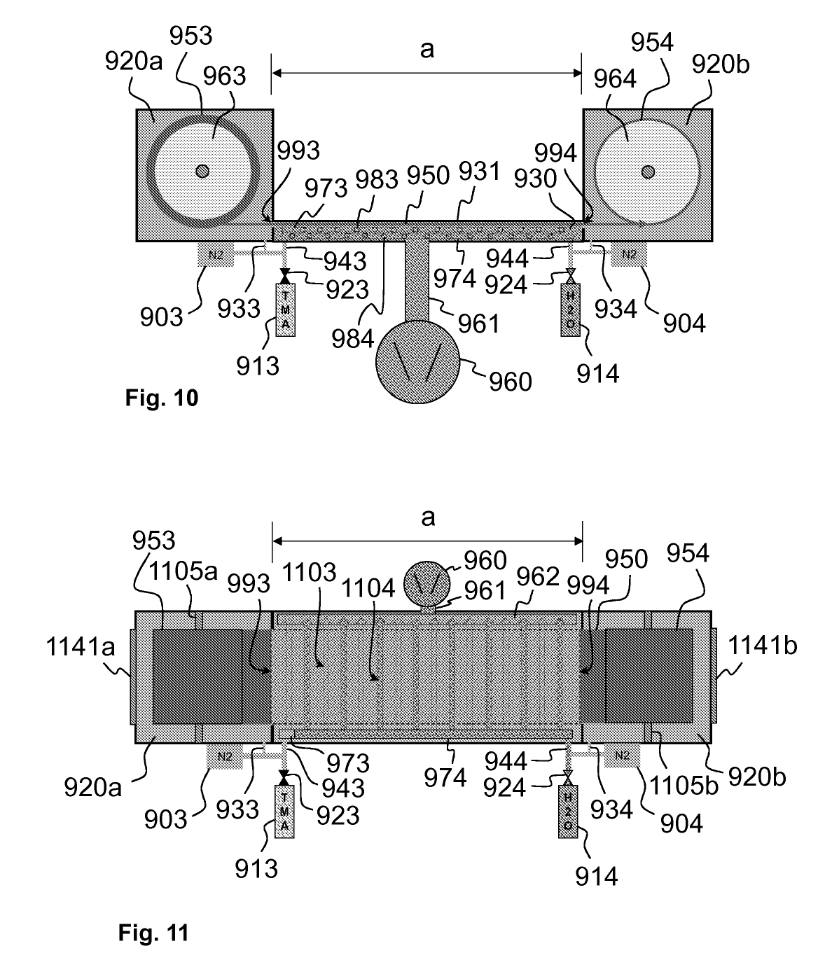

FIG. 10 shows the deposition reactor of FIG. 9 in operation during a precursor exposure period in accordance with an example embodiment. The pulsing valve 924 is opened. Precursor vapor of H₂O precursor flows into the processing chamber via in-feed line 944 and into the reaction space 930 via apertures 984. The precursor vapor fills the reaction space 930 and reacts with the reactive sites on substrate web surface in accordance with ALD growth mechanism. Since the pulsing valve 923 is closed, only inactive gas flows into the reaction space via apertures 983. Inactive gas, gaseous reaction by-products (if any) and residual reactant molecules (if any) flow as a horizontal flow into the exhaust line 961 and finally to the vacuum pump 960.

As mentioned in the preceding, the pressure difference between the reaction space 930 and the confined space(s) 920a and 920b where the rolls 953 and 954 are located forms a barrier at the slits 993 and 994. The precursor vapor flow is in that way prevented from flowing from the reaction space 930 into the confined space(s) 920a and 920b. Due to the pressure difference, however, flow from the other direction (that is, from the confined space(s) 920a and 920b to the reaction space through the slits 993 and 994) is possible. Inactive gas is fed via the in-feed channels 933 and 934 into the confined spaces 920a and 920b, respectively. The pressure difference is maintained by the throttle function caused by the slits 993 and 994.

FIG. 11 shows a top view of the deposition reactor of FIGS. 9 and 10 during the H₂O precursor exposure period in accordance with an example embodiment. Visible in FIG. 11 are the doors 1141a and 1141b through which the source and destination rolls 953 and 954, respectively, can be loaded to and unloaded from the deposition reactor. Visible are also roll axis 1105a and 1105b of the respective rolls 953 and 954. The deposition reactor comprises one or more drives (not shown in FIG. 11) connected to the roll axis 1105a and/or 1105b to rotate the rolls 953 and 954. The arrows 1104 depict precursor vapor flow from the shower head channel 974 to a collecting channel 962. The form and place of the collecting channel depends on the implementation. In the embodiment shown in FIG. 11 the collecting channel is located at the side of the reaction space. The collecting channel 962 in FIG. 11 it extends substantially throughout the total length a of the reaction space. The collecting channel is in fluid communication with the exhaust line 961 leading to the vacuum pump 960. The arrows 1103 depict inactive gas flow from the shower head channel 973 to the collecting channel 962 and therefrom to the exhaust line 961.

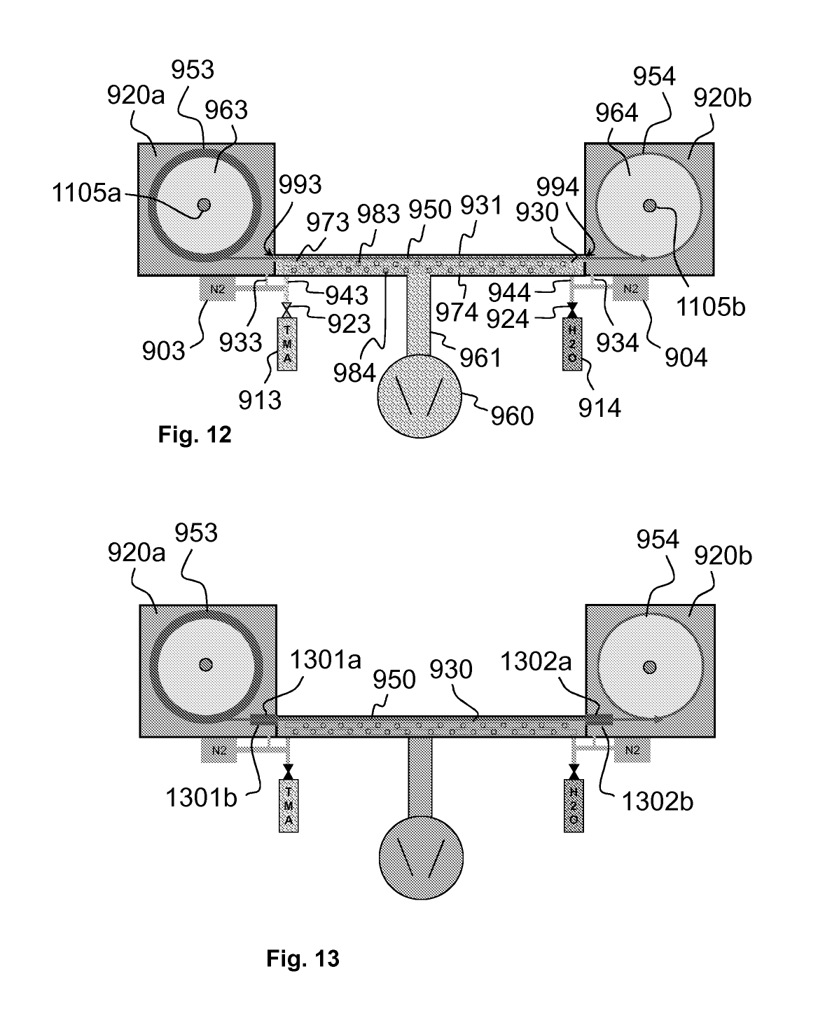

FIG. 12 shows the deposition reactor of FIGS. 9-11 in operation during the exposure period of the other precursor in accordance with an example embodiment. The pulsing valve 923 is opened. Precursor vapor of TMA precursor flows into the processing chamber via in-feed line 943 and into the reaction space 930 via apertures 983. The precursor vapor fills the reaction space 930 and reacts with the reactive sites on substrate web surface in accordance with ALD growth mechanism. Since the pulsing valve 924 is closed, only inactive gas flows into the reaction space via apertures 984. Inactive gas, gaseous reaction by-products (if any) and residual reactant molecules (if any) flow as a horizontal flow into the exhaust line 961 and finally to the vacuum pump 960.

A deposition sequence is formed of one or more consecutive deposition cycles, each cycle consisting of at least a first precursor exposure period (pulse A) followed by a first purge step (purge A) followed by a second precursor exposure period (pulse B) followed by a second purge step (purge B). Herein, if for example aluminum oxide Al₂O₃ is the deposited material the TMA precursor may be the first precursor (pulse A) and the water precursor may be the second precursor (pulse B).

The thickness of grown material is determined by the speed of the web. As an example, the length a of the reaction space 930 may be 100 cm. The deposition cycle may consist of a TMA pulse of 0.1 s, N2 purge of 0.3 s, H2O pulse of 0.1 s, and N2 purge of 0.5 s. The total cycle period therefore is 1 s. If it is estimated that a monolayer of Al2O3 is around 0.1 nm the following applies:

If the speed of the web is 1 cm/cycle there will be 100 cycles; this will take 1.66 min, and a 10 nm coating of Al2O3 will be deposited.

If the speed of the web is 0.5 cm/cycle there will be 200 cycles; this will take 3.33 min, and a 20 nm coating of Al2O3 will be deposited.

If the speed of the web is 0.1 cm/cycle there will be 1000 cycles; this will take 16.66 min, and a 100 nm coating of Al2O3 will be deposited.

FIGS. 9-12 are simplified figures so they do not show for example any heaters and other typical parts or elements that the deposition reactor may contain, and the use of which is known as such.

FIG. 13 shows the deposition reactor of FIGS. 9-12 with constriction plates in accordance with an example embodiment. As described in the foregoing, the substrate web was input into the reaction space and output from the reaction space via slits. The embodiment of FIG. 13 shows constriction plates forming said slits. In the embodiment of FIG. 13 there are two constriction plates 1301a and 1301b placed next to each other at the interface between the confined space 920a and the reaction space 930. The substrate web 950 just hardly fits to pass through between the plates. Similarly, at the interface between the reaction space 930 and the confined space 920a there is another pair of constriction plates 1302a and 1302b. The constriction plates may be parallel plates so that the space between the plates (slit volume) becomes elongated in the web moving direction.

As to the other structural and functional features of the embodiment of FIG. 13 a reference is made to the embodiments described in the foregoing with reference to FIGS. 9-12 and related description.

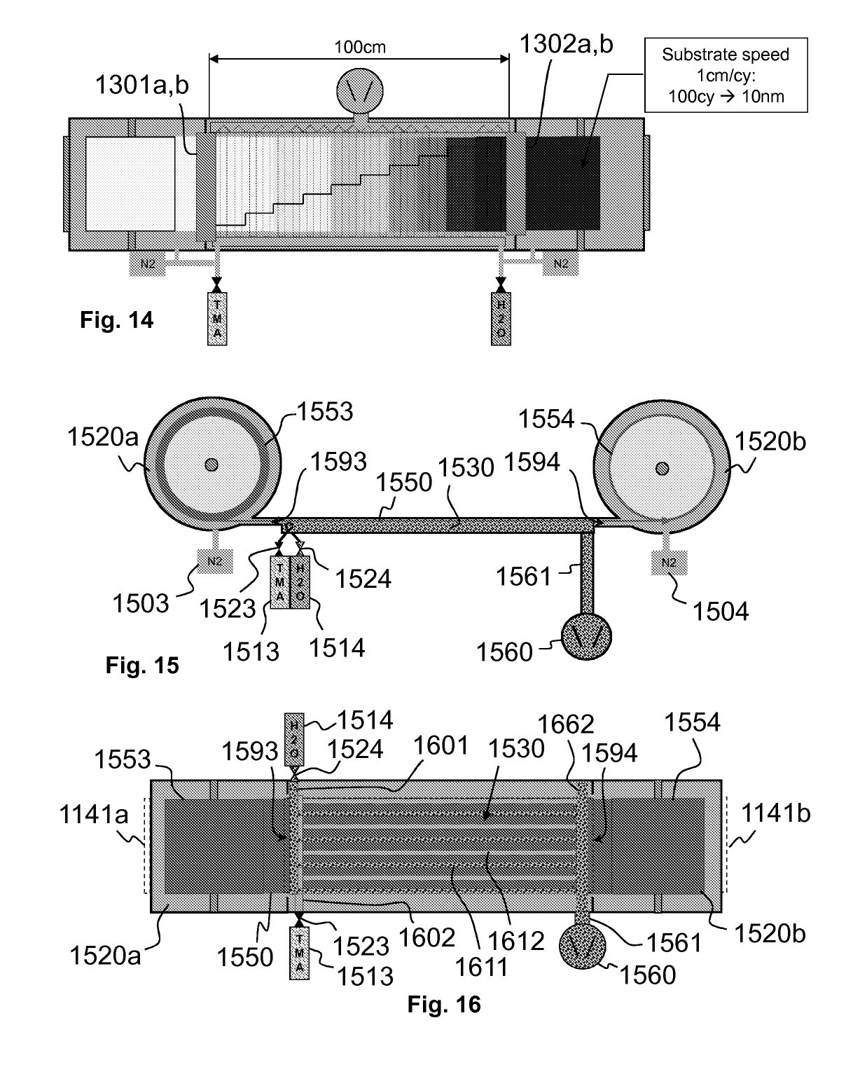

FIG. 14 roughly shows the thickness of deposited material in the function of distance traveled within a reaction space in accordance with an example embodiment. In this example, the substrate web enters the reaction space via the input slit formed by the constriction plates 1301a, b similarly as shown in the embodiment of FIG. 13. The thickness of deposited material gradually grows as indicated by the curve and different colors in FIG. 13 when the substrate web travels towards the output slit formed by the constriction plates 1302a, b. If the average speed of the web is 1 cm/cycle and the length of the reaction space is 100 cm, the thickness in the end is 10 nm in this example. The growth curve in FIG. 13 indicates that the substrate web has been moved 10 cm in every 10 cycles. However, in other embodiments it is possible to move the substrate web after every cycle. Or the movement of the substrate web may continuous movement.

The in-feed of precursor vapor into the reaction space can be with or without shower head channels from one or both of the sides of the reaction space. In alternative embodiments, the in-feed of precursor vapor can be by in-feed head(s) from the substrate web input end of the reaction space, or alternatively from both the substrate web input and output ends of the reaction space. Depending on the embodiment, the exhaust line and a possible collecting channel can be conveniently arranged on the other side of the reaction space than the in-feed, at the substrate web output end of the reaction space, or at the middle area of the reaction space.

FIG. 15 shows a deposition reactor with precursor vapor in-feed at the substrate web input end of the processing chamber in accordance with an example embodiment. The reactor comprises a processing chamber providing a reaction space 1530. A source roll 1553 resides in a first confined space 1520a, and a destination roll 1554 in a second confined space 1520b.

A first pulsing valve 1523 controls the flow of precursor vapor of a first precursor from a first precursor source 1513, and a second pulsing valve 1524 controls the flow of precursor vapor of a second precursor from a second precursor source 1514. A first inactive gas source 1503 is in fluid communication with a confined space 1520a that contains a first (source) substrate web roll 1553. A second inactive gas source 1504 is in fluid communication with a confined space 1520b that will contain a second (destination) substrate web roll 1554. However, the inactive gas sources 1503 and 1504 may be implemented as a single source in some example embodiments, and they may also be in fluid communication with precursor vapor in-feed lines.

A substrate web 1550 is driven from the source roll 1553 into the reaction space 1530 via an input slit 1593 at the substrate web input end of the reaction space 1530. The track of the substrate web follows the upper wall of the processing chamber. However, other routes and constructions are possible. ALD deposition occurs in the reaction space 1530. The substrate web is driven from the reaction space 1530 onto the destination roll 1554 via an output slit 1594 at the substrate web output end of the reaction space 1530.

The first and second confined spaces 1520a,b are excess pressure volumes compared to the pressure in the reaction space 1530. The excess pressure is maintained by the slits 1593 and 1594 as well as by feeding inactive gas into the excess pressure volumes from the inactive gas source(s) 1503 and 1504.

Precursor vapor of the second precursor is fed into the reaction space at the substrate web input end during the second precursor exposure period, as depicted in FIG. 15. The precursor vapor is fed by an in-feed head 1601, as better depicted by FIG. 16, where FIG. 16 shows a top view of the type of deposition reactor of FIG. 15 during the second precursor vapor exposure period in accordance with an example embodiment. The in-feed head 1601 may extend substantially throughout the total width of the reaction space 1530. During a first precursor exposure period, precursor vapor of the first precursor is fed by a corresponding in-feed head 1602 at the substrate web input end. During the second precursor exposure period, however, merely inactive gas in guided from the in-feed head 1602 into the reaction space 1530. During the second precursor exposure period, the precursor vapor of the second precursor flows (as indicated by arrows 1611) along the substrate web surface in the substrate web moving direction into an exhaust line 1561 at the substrate web output end of the reaction space 1530. Similarly, inactive gas from the in-feed head 1602 flows (as indicated by arrows 1612) along the substrate web moving direction into the exhaust line 1561 at the substrate web output end of the reaction space 1530. In certain example embodiments, the deposition reactor comprises a collecting channel 1662 at the substrate web output end of the reaction space 1530. The collecting channel 1662 in FIG. 16 extends substantially throughout the total width of the reaction space 1530. The collecting channel 1662 is in fluid communication with the exhaust line 1561 leading to the vacuum pump 1560, and it collects the gases evacuating from the reaction space 1530 leading them into the exhaust line 1561 and finally to the vacuum pump 1560.

FIG. 16 also shows doors 1141a and 1141b in opposite ends of the deposition reactor via which the source and destination rolls 1553, 1554 may be loaded and unloaded.

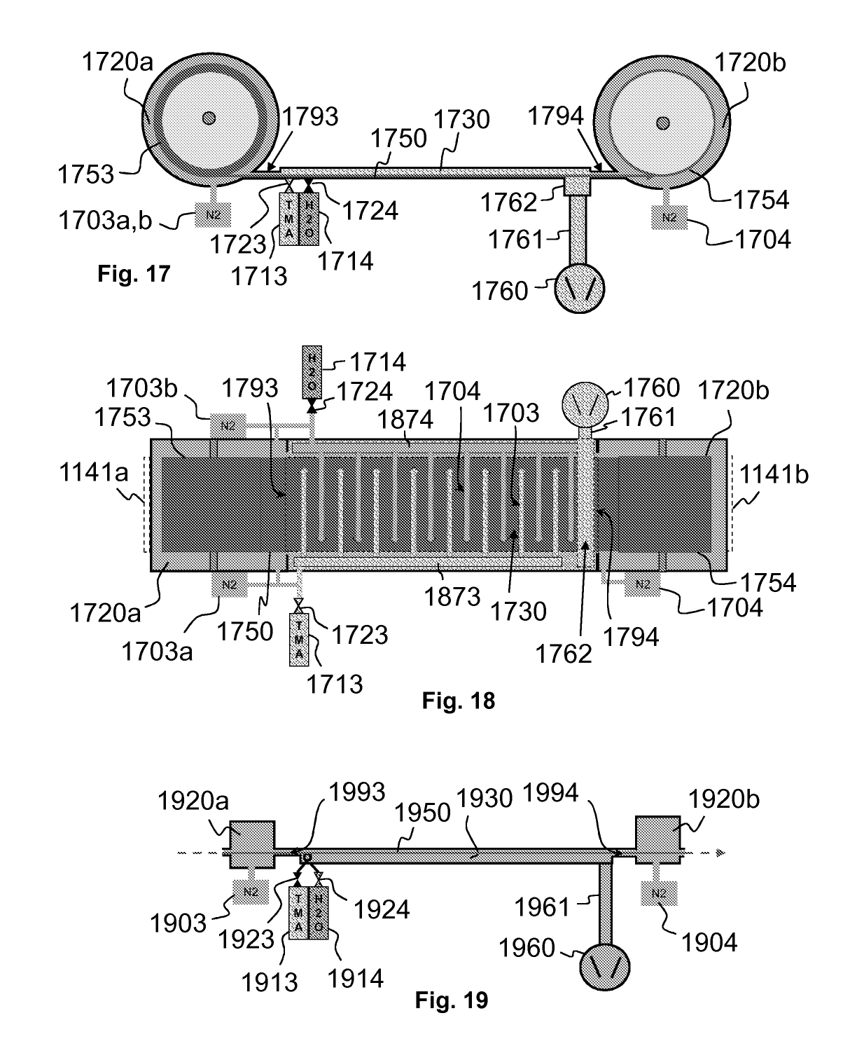

FIG. 17 shows a deposition reactor with precursor vapor in-feed at the side of the processing chamber in accordance with an example embodiment. The reactor comprises a processing chamber providing a reaction space 1730. A source roll 1753 resides in a first confined space 1720a, and a destination roll 1754 in a second confined space 1720b.

A first pulsing valve 1723 controls the flow of precursor vapor of a first precursor from a first precursor source 1713, and a second pulsing valve 1724 controls the flow of precursor vapor of a second precursor from a second precursor source 1714. A first inactive gas source 1703a is in fluid communication with a confined space 1720a that contains a first (source) substrate web roll 1753 and with an in-feed line from the first precursor source 1713. A second inactive gas source 1703b is in fluid communication with the confined space 1720a and with an in-feed line from the second precursor source 1714. A third inactive gas source 1704 is in fluid communication with a confined space 1720b that will contain a second (destination) substrate web roll 1754. However, the inactive gas sources 1703a and b, or 1703a and b as well as 1704 may be implemented as a single source in some example embodiments.

A substrate web 1750 is driven from the source roll 1753 into the reaction space 1730 via an input slit 1793 at the substrate web input end of the reaction space 1730. The track of the substrate web follows the lower wall of the processing chamber. However, other routes and constructions are possible. ALD deposition occurs in the reaction space 1730. The substrate web is driven from the reaction space 1730 onto the destination roll 1754 via an output slit 1794 at the substrate web output end of the reaction space 1730.

The first and second confined spaces 1720a,b are excess pressure volumes compared to the pressure in the reaction space 1730. The excess pressure is maintained by the slits 1793 and 1794 as well as by feeding inactive gas into the excess pressure volumes from the inactive gas source(s) 1703a,b and 1704.

Precursor vapor of the first precursor is fed into the reaction space 1730 from a side of the reaction space 1730. The precursor vapor is fed via a showerhead channel 1873, as better depicted by FIG. 18, where FIG. 18 shows a top view of the type of deposition reactor of FIG. 17 during the first precursor vapor exposure period in accordance with an example embodiment. The showerhead channel 1873 may extend substantially throughout the total length of the reaction space 1730. During a second precursor exposure period, precursor vapor of the second precursor is fed by a corresponding showerhead channel 1874 from the opposite side of the reaction space 1730. During the first precursor exposure period, however, merely inactive gas in guided from the showerhead channel 1874 into the reaction space 1730. During the first precursor exposure period, the precursor vapor of the first precursor flows (as indicated by arrows 1703) along the substrate web surface first in a traverse direction but the flow direction later turns towards the collecting channel 1762 at the substrate web output end of the reaction space 1730 drawn by the vacuum pump 1760. Similarly, inactive gas from showerhead channel 1874 flows (as indicated by arrows 1704) along the substrate web surface first in a traverse direction but the flow direction later turns towards the collecting channel 1762. The collecting channel 1762 in FIG. 18 extends substantially throughout the total width of the reaction space 1730. The collecting channel 1762 is in fluid communication with the exhaust line 1761 leading to the vacuum pump 1760, and it collects the gases evacuating from the reaction space 1730 leading them into the exhaust line 1761 and finally to the vacuum pump 1760.

FIG. 18 also shows doors 1141a and 1141b in opposite ends of the deposition reactor via which the source and destination rolls 1753, 1754 may be loaded and unloaded.

As mentioned in the preceding the deposition reactor may be a standalone apparatus or it may form part of a production line. FIG. 19 shows the deposition reactor as a part of a production line.

A first pulsing valve 1923 of the deposition reactor controls the flow of precursor vapor of a first precursor from a first precursor source 1913, and a second pulsing valve 1924 controls the flow of precursor vapor of a second precursor from a second precursor source 1914. A first inactive gas source 1903 is in fluid communication with a confined space 1920a. A second inactive gas source 1904 is in fluid communication with a confined space 1920b. However, the inactive gas sources 1903 and 1904 may be implemented as a single source in some example embodiments, and they may also be in fluid communication with precursor vapor in-feed lines.

A substrate web 1950 enters the processing chamber 1930 of the deposition reactor from a previous processing stage via the first confined space 1920a and via an input slit 1993 at the substrate web input side of the reactor. ALD deposition occurs in the reaction space 1930. The substrate web is guided from the reaction space 1530 to a following processing stage of the production line via an output slit 1994 and via the second confined space 1920b at the substrate web output side of the reactor.

The first and second confined spaces 1920a,b are excess pressure volumes compared to the pressure in the reaction space 1930. The excess pressure is maintained by the slits 1993 and 1994 as well as by feeding inactive gas into the excess pressure volumes from the inactive gas source(s) 1903 and 1904.

The in-feed of precursor vapor into the reaction space 1930 as well as evacuating gases from the reaction space 1930 via an exhaust line 1961 to a vacuum pump 1960 may occur similarly as described in connection with the embodiment shown in FIGS. 15 and 16 and in related description.

In a yet another embodiment, the excess pressure volumes may be omitted. The substrate web 1950 may enter the processing chamber 1930 without passing through any first confined space 1920a. If required by the production process, in this embodiment, an entry to the processing chamber and outlet from the processing chamber simply should be tight enough with proper dimensioning or sealing.

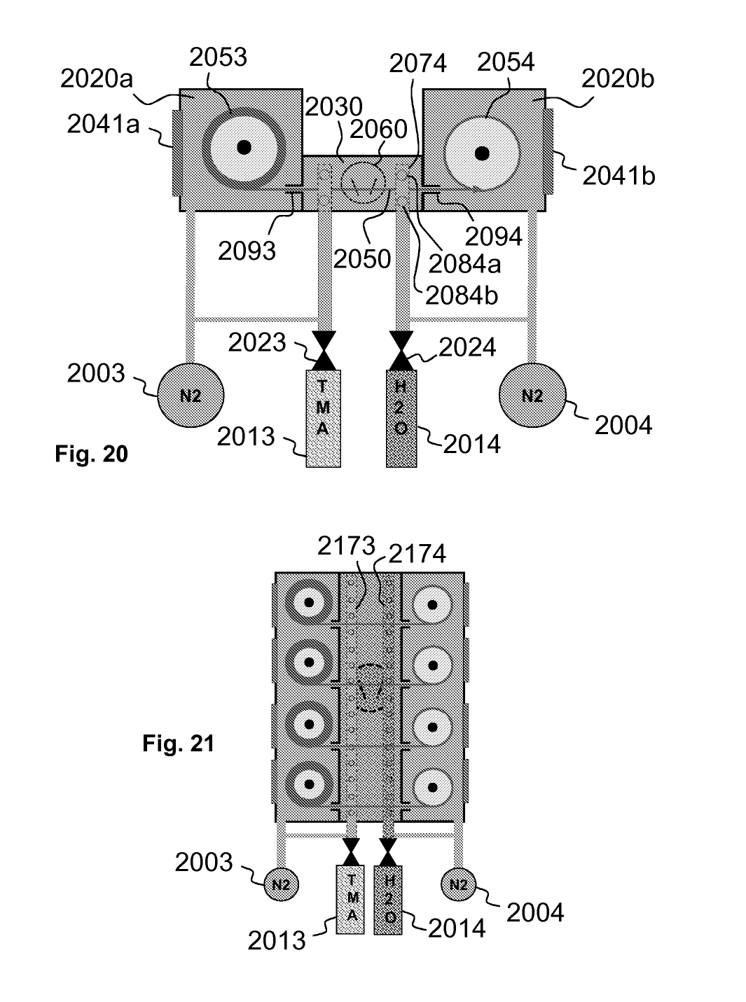

FIG. 20 shows a top view of a deposition reactor in accordance with yet another example embodiment. The deposition reactor comprises first and second inactive gas sources 2003 and 2004, and first and second precursor sources 2013 and 2014, as well as first and second pulsing valves 2023 and 2024. The inactive gas sources 2003 and 2004 are in fluid communication with confined spaces (excess pressure volumes) 2020a and 2020b where the rolls 2053 and 2054 reside. The rolls can be loaded and unloaded through doors 2041a and 2041b. The substrate web 2050 is driven from roll-to-roll via the processing chamber 2030 and slits 2093 and 2094 (here: with constriction plates), and is ALD processed in the meantime in the processing chamber 2030. As to the basic structural and functional features of the embodiment of FIG. 20 a reference is therefore made to the preceding embodiments described in the foregoing. A difference to the preceding embodiments is in the showerhead channels (via which precursor vapor in-feed occurs) within the reaction space. A first showerhead channel configured to feed precursor vapor of the first precursor travels within the processing chamber 2030 in the direction of desired material growth. The first showerhead channel has at least one aperture on both sides of the substrate web (in the direction of desired material growth). Similarly, a second showerhead channel 2074 configured to feed precursor vapor of the second precursor travels within the processing chamber 2030 in the direction of desired material growth. The second showerhead channel 2074 has at least one aperture 2084a,b on both sides of the substrate web. The exhaust to the vacuum pump 2060 is at the middle area of the processing chamber (or reaction space) 2030 on the bottom of the processing chamber.

FIG. 21 shows a top view of a deposition reactor for deposition of multiple rolls at a time in accordance with an example embodiment. Each of the rolls have their own separate entries into the processing chamber. The first and second showerhead channels 2173 and 2174 travel within the processing chamber in the direction of desired material growth. The showerhead channels have at least one aperture on both sides of each of the substrate webs. Otherwise, as to the basic structural and functional features of the embodiment of FIG. 21 a reference is made to what has been presented in FIG. 20 and in related description.

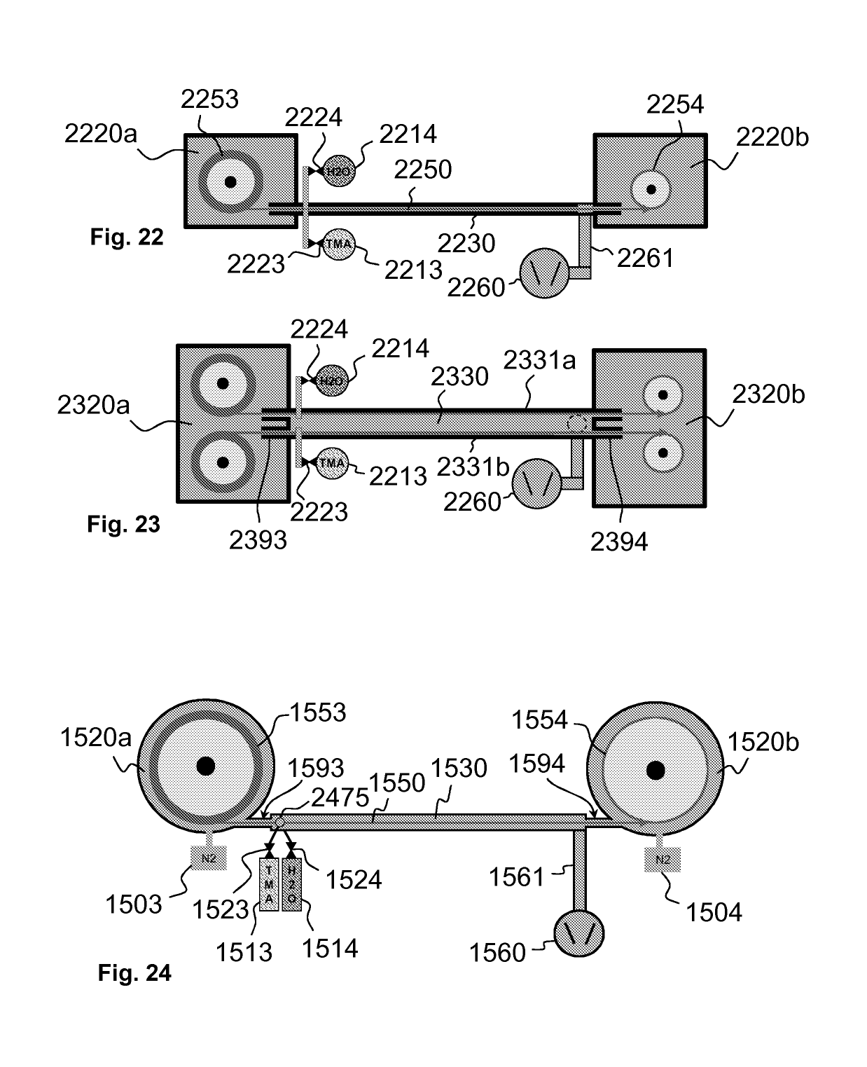

FIG. 22 shows a thin reactor structure in accordance with an example embodiment. The deposition reactor comprises first and second inactive gas sources (not shown), and first and second precursor sources 2213 and 2214, as well as first and second pulsing valves 2223 and 2224. The inactive gas sources are in fluid communication (not shown) with confined spaces (excess pressure volumes) 2220a and 2220b where the rolls 2253 and 2254 reside. The substrate web 2250 is driven from roll-to-roll via a processing chamber 2230, and is ALD processed in the meantime in the processing chamber 2230. Precursor vapor in-feed is at the substrate web input end of the processing chamber 2230. An exhaust line 2261 directing towards a vacuum pump 2260 resides at the substrate web output end of the processing chamber 2230. As to the basic structural and functional features of the embodiment of FIG. 22 a reference is therefore made to the preceding embodiments described in the foregoing. A difference to the preceding embodiments is in the processing chamber 2230. In this embodiment, a slit extends from the first confined space 2220a all the way to the second confined space 2220b. The slit therefore forms the thin processing chamber 2230.

FIG. 23 shows a thin reactor structure for deposition of multiple rolls in accordance with an example embodiment. Each of the rolls have their own input slits 2393 into the processing chamber 2330 as well as their own separate output slits 2394 out from the processing chamber 2330. The source rolls reside in a first confined space (excess pressure volume) 2320a and the destination rolls in a second confined space (excess pressure volume) 2320b. In the embodiment shown in FIG. 23 the outer sides of the slits 2393 and 2394 forms the outer sides 2331a, 2331b of the thin processing chamber wall. Otherwise, as to the basic structural and functional features of the embodiment of FIG. 23 a reference is made to what has been presented in FIG. 22 and in related description.

The preceding embodiments in which the substrate web travels close to the processing chamber wall (in the direction of desired material growth) suit well for single-sided deposition, whereas embodiments in which the substrate travels in the center area of the processing chamber/reaction space suit well for double-sided deposition.

FIG. 24 shows double-sided coating in accordance with an example embodiment. The deposition reactor shown in FIG. 24 basically corresponds to the deposition reactor in FIG. 15. As to the features of FIG. 24 already known from FIG. 15 a reference is made to FIG. 15 and related description. Contrary to the embodiment of FIG. 15 in which the substrate web travels close to the upper wall of the processing chamber, the substrate web in the embodiment of FIG. 24 travels along the center area of the processing chamber/reaction space 1530. The deposition reactor comprises precursor vapor in-feed heads 2475 of each precursor on both sides of the substrate web surface for double-sided deposition.

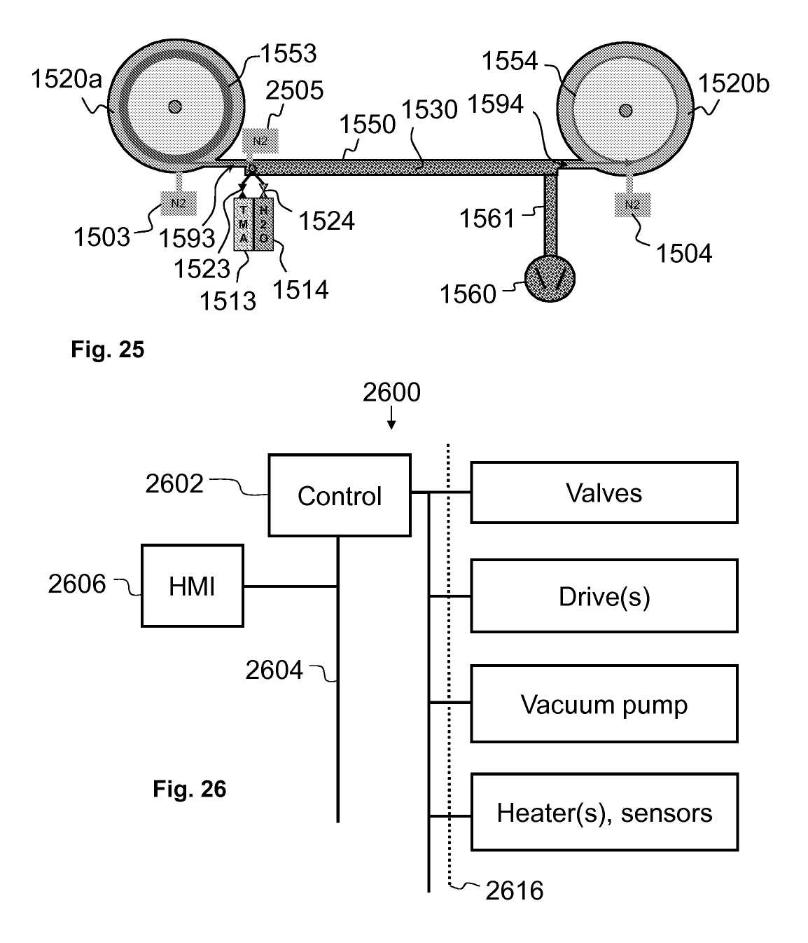

In certain example embodiments, the placement of the track of the substrate web within the processing chamber or reaction space is adjustable. The placement of the track may be adjusted based on present needs. It may be adjusted for example by adjusting the placement of the input and output slits in relation to the processing chamber (or reaction space). As mentioned, for double-sided deposition, the substrate web may travel in the center area of the processing chamber, whereas for single-sided deposition the substrate web may travel close to the processing chamber wall. FIG. 25 shows a deposition reactor and a specific detail for single-sided deposition. The deposition reactor of FIG. 25 basically corresponds to the deposition reactor of FIG. 15. The substrate web 1550 travels close to a first (here: upper) wall of the processing chamber. Inactive gas is fed from an inactive gas source 2505 (which may be the same or different source as the source 1503 and/or 1504) into the space between the backside (i.e., the side or surface that is not to be coated) of the substrate web and the first wall. The inactive gas fills the space between the backside of the substrate web and the first wall. The inactive gas thereby forms a shielding volume. The other surface of the substrate web is coated by sequential self-saturating surface reactions. The actual reaction space is formed in the volume between the surface to be coated and a second wall (opposite to the first wall) of the processing chamber. Reactive gas does not substantially enter the shielding volume. This is partly due to the inactive gas flow into the shielding volume, and partly because of the substrate web itself prevents the flow to the backside of the substrate web from the other side of the web.

In an example embodiment, the deposition reactor (or reactors) described herein is a computer-controlled system. A computer program stored into a memory of the system comprises instructions, which upon execution by at least one processor of the system cause the deposition reactor to operate as instructed. The instructions may be in the form of computer-readable program code. FIG. 26 shows a rough block diagram of a deposition reactor control system 2600. In a basic system setup process parameters are programmed with the aid of software and instructions are executed with a human machine interface (HMI) terminal 2606 and downloaded via a communication bus 2604, such as Ethernet bus or similar, to a control box 2602 (control unit). In an embodiment, the control box 2602 comprises a general purpose programmable logic control (PLC) unit. The control box 2602 comprises at least one microprocessor for executing control box software comprising program code stored in a memory, dynamic and static memories, I/O modules, A/D and D/A converters and power relays. The control box 2602 sends electrical power to pneumatic controllers of appropriate valves of the deposition reactor. The control box controls the operation of the drive(s), the vacuum pump, and any heater(s). The control box 2602 receives information from appropriate sensors, and generally controls the overall operation of the deposition reactor. The control box 2602 controls driving a substrate web in an atomic layer deposition reactor from a first roll via a reaction space to a second roll. By adjusting the speed of the web the control box controls the growth of deposited material, i.e., material thickness. The control box 2602 further controls exposing the reaction space to temporally separated precursor pulses to deposit material on said substrate web by sequential self-saturating surface reactions. The control box 2602 may measure and relay probe readings from the deposition reactor to the HMI terminal 2606. A dotted line 2616 indicates an interface line between the deposition reactor parts and the control box 2602.

Without limiting the scope and interpretation of the patent claims, certain technical effects of one or more of the example embodiments disclosed herein are listed in the following: A technical effect is a simpler structure compared to spatial roll-to-roll ALD reactors. Another technical effect is that the thickness of deposited material is directly determined by the speed of the web. Another technical effect is optimized consumption of precursors due to a thin processing chamber structure.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1. A method comprising:
driving a substrate web into a reaction space of an atomic layer deposition reactor; and
exposing the reaction space to temporally separated precursor pulses to deposit material on said substrate web by sequential self-saturating surface reactions.

2. The method of claim 1, comprising:
inputting the substrate web from an excess pressure volume into the reaction space via a slit maintaining a pressure difference between said volume and the reaction space.

3. The method of claim 2, wherein the reactor comprises constriction plates forming said slit.

4. The method of any preceding claim, wherein the thickness of deposited material is controlled by the speed of the web.

5. The method of any preceding claim 2-4, comprising:
feeding inactive gas into the excess pressure volume.

6. The method of any preceding claim, wherein the precursor vapor flow direction in the reaction space is along the moving direction of the substrate web.

7. The method of claim 6, comprising:
feeding precursor vapor into the reaction space at the substrate web input end of the reaction space and arranging exhaust of gases at the substrate web output end of the reaction space.

8. The method of any preceding claim, wherein the precursor vapor flow direction in the reaction space is traverse compared to the moving direction of the substrate web.

9. The method of claim 8, comprising:
feeding precursor vapor into the reaction space at a side of the reaction space and arranging exhaust of gases at an opposite side of the reaction space.

10. The method of any preceding claim, comprising:
integrating the first and second roll into a reaction chamber lid.

11. The method of any preceding claim, comprising:
driving said substrate web straight through said reaction space.

12. An apparatus comprising:
a driving unit configured to drive a substrate web into a reaction space of an atomic layer deposition reactor; and
a precursor vapor feeding part configured to expose the reaction space to temporally separated precursor pulses to deposit material on said substrate web by sequential self-saturating surface reactions.

13. The apparatus of claim 12, comprising:
an input slit for inputting the substrate web from an excess pressure volume into the reaction space.

14. The apparatus of claim 13, comprising constriction plates forming said slit.

15. The apparatus of any preceding claim 12-14, comprising:
a channel configured to convey inactive gas into the excess pressure volume.

16. The apparatus of any preceding claim 12-15, comprising:
a precursor vapor in-feed opening at the substrate web input end of the reaction space and exhaust at the substrate web output end of the reaction space.

17. The apparatus of any preceding claim 12-16, comprising:
a precursor vapor in-feed opening or openings at a side of the reaction space and exhaust at an opposite side of the reaction space.

18. The apparatus of any preceding claim 12-17, comprising:
a reaction chamber lid configured to receive the first and second roll.

19. An apparatus comprising:
means for driving a substrate web into a reaction space of an atomic layer deposition reactor; and
means for exposing the reaction space to temporally separated precursor pulses to deposit material on said substrate web by sequential self-saturating surface reactions.
